(19) United States
(12) Patent Application Publication
(10) Pub. No.: US 2025/0321258 A1
(43) Pub. Date: Oct. 16, 2025

(54) SURFACE WAVEGUIDE

(71) Applicant: Quaise Energy, Inc., Cambridge, MA (US)

(72) Inventors: Justin David Elroy Lamb, Arcola, TX (US); Alexander Siy, Houston, TX (US); Dmitry Shchegolkov, Pearland, TX (US); Hy Phan, Houston, TX (US); Casey Rodgers, Pearland, TX (US); Francesco Vaghi, Houston, TX (US); Marco Quilico, Pearland, TX (US); Andres Calabressi, Sugar Land, TX (US); Stephen Jeske, Manvel, TX (US); Hin Y. Lee, Pearland, TX (US)

(21) Appl. No.: 19/174,758

(22) Filed: Apr. 9, 2025

Related U.S. Application Data
(60) Provisional application No. 63/632,378, filed on Apr. 10, 2024.

(51) Int. Cl. G01R 29/08; E21B 7/15; E21B 21/16; G01R 31/12; H01P 3/12; H05H 1/00; H05K 7/20

(52) U.S. Cl. CPC G01R 29/0878; E21B 7/15; E21B 21/16; G01R 31/1218; H01P 3/122; H05H 1/01; H05K 7/20

(57) ABSTRACT

An enclosure is configured to receive an electromagnetic wave from a mm wave emitter by a first waveguide positioned between the mm wave emitter and the enclosure. The enclosure includes one or more components configured to manage transmission of the electromagnetic wave in the first mode to a second waveguide positioned relative to a borehole of a well to be formed by the electromagnetic wave transmitted through the second waveguide. The components can include a first port at which a gas is received, a focusing mirror, a frequency sensor, a power measurement sensor, an arc detector, a cooled wire grid, a load cell provided on an exterior surface of the enclosure, or a barrier window. Related apparatus, systems, techniques, and articles are also described.

### CROSS-REFERENCE TO RELATED APPLICATIONS

This application claims the benefit of U.S. Provisional Application No. 63/632,378, filed on Apr. 10, 2024, entitled “Surface Waveguide,” the entirety of which is incorporated by reference herein.

### TECHNICAL FIELD

The subject matter described herein relates to a waveguide for use in transmitting electromagnetic waves.

### BACKGROUND

A waveguide is a structure that guides waves, such as electromagnetic waves or sound, with minimal loss of energy by restricting the transmission of energy to one direction. Waveguides can be used in non-conventional drilling techniques, such as thermal drilling and/or millimeter wave drilling, to form a borehole of a well. Waveguides can be used to transmit electromagnetic waves into the borehole to enable drilling at deeper subsurface depths than conventional, rotary drilling. Specific internal features, such as corrugated grooves, can be included in a waveguide and can enhance the transmission efficiency of the electromagnetic waves provided into the borehole. Forming and deploying corrugated waveguides in single lengths of tubes can be expensive, require specialized materials and equipment, and be prone to manufacturing errors which can result in inventory waste, operational downtime of a well, and inefficient transmission of electromagnetic energy.

### SUMMARY

An example implementation of the subject matter described within this disclosure is a system with the following features. A millimeter (mm) wave emitter is configured to emit an electromagnetic wave in a first mode. An enclosure is configured to receive the electromagnetic wave from the mm wave emitters via a first set of waveguides positioned between the mm wave emitter and the enclosure. The enclosure includes several components configured to manage transmission of the electromagnetic wave in the first mode to a second waveguide positioned relative to a borehole of a well to be formed via the electromagnetic wave transmitted through the second waveguide. The set of components includes at least one of the following. A first port at which a gas is received. At least one mirror configured to adjust a direction or a diameter of the electromagnetic wave provided to the second waveguide. A frequency sensor configured to sample the electromagnetic wave can be included. At least one power measurement sensor configured to measure a power of the electromagnetic wave can be included. At least one arc detector configured to detect an arc event responsive to transmitting the electromagnetic wave to the second waveguide can be included. A cooled wire grid configured to direct electromagnetic radiation in the first mode reflected from the borehole away from the mm wave emitter can be included. A load cell provided on an exterior surface of the enclosure can be included.

Aspects of the example system, which can be combined with the example system alone or in combination with other aspects, can include the following. The first mode is an HE₁₁ mode.

Aspects of the example system, which can be combined with the example system alone or in combination with other aspects, can include the following. The first set of waveguides are coupled via one or more miter bends.

Aspects of the example system, which can be combined with the example system alone or in combination with other aspects, can include the following. The first set of waveguides and/or the one or more miter bends include a corrugation features on an inner surface on each waveguide of the first set of waveguides and an inner surface of the one or more miter bends. The corrugation are features configured to maintain the electromagnetic wave in the first mode as the electromagnetic wave propagates through the first set of waveguides and/or the one or more miter bends.

Aspects of the example system, which can be combined with the example system alone or in combination with other aspects, can include the following. The corrugation features are configured to maintain the first mode of the electromagnetic wave.

Aspects of the example system, which can be combined with the example system alone or in combination with other aspects, can include the following. Alternatively or in addition, the example system includes one or more bends in place of the one or more miter bends.

Aspects of the example system, which can be combined with the example system alone or in combination with other aspects, can include the following. A barrier window is positioned between the mm wave emitter and the borehole. The barrier window is configured to protect the mm wave emitter from a vacuum force or a pressure force.

Aspects of the example system, which can be combined with the example system alone or in combination with other aspects, can include the following. At least one miter bend of the one or more miter bends includes a mirror therein.

Aspects of the example system, which can be combined with the example system alone or in combination with other aspects, can include the following. The mirror includes a diffraction grating on a surface of the mirror.

Aspects of the example system, which can be combined with the example system alone or in combination with other aspects, can include the following. The diffraction grating is configured to direct electromagnetic radiation reflected from the borehole away from the mm wave emitter.

Aspects of the example system, which can be combined with the example system alone or in combination with other aspects, can include the following. The first set of waveguides and/or the second waveguide include one or more tapered portions. A first end of a tapered portion is adjacent to at least one miter bend and a second end of the tapered portion is opposite the first end. The first end has a larger diameter than the second end.

Aspects of the example system, which can be combined with the example system alone or in combination with other aspects, can include the following. The cooled wire grid is cooled by a phase change refrigerant supplied to the wire grid.

Aspects of the example system, which can be combined with the example system alone or in combination with other aspects, can include the following. The mm wave emitter is positioned on a surface of earth through which the borehole of the well is formed. The enclosure is positioned above the borehole of the well. The electromagnetic wave is a millimeter electromagnetic wave.

Aspects of the example system, which can be combined with the example system alone or in combination with other aspects, can include the following. The at least one mirror is configured to adjust the direction of the electromagnetic wave towards the borehole.

Aspects of the example system, which can be combined with the example system alone or in combination with other aspects, can include the following. The direction of the electromagnetic wave is provided to the second waveguide is adjusted by a mirror and the diameter of the electromagnetic wave of provided to the second waveguide is adjusted by a focusing mirror.

Aspects of the example system, which can be combined with the example system alone or in combination with other aspects, can include the following. The frequency sensor is coupled to a computing device configured to determine if a sampled frequency of the electromagnetic wave is within a predetermined range of values stored in a memory of the computing device.

Aspects of the example system, which can be combined with the example system alone or in combination with other aspects, can include the following. A diagnostic sampling device is coupled to the enclosure. The diagnostic sampling device is configured to measure at least one of a temperature, a standoff, mode purity, plasma formation, and a geometry of the hole. mm wave emitter

Aspects of the example system, which can be combined with the example system alone or in combination with other aspects, can include the following. The at least one power measurement sensor includes a first sensor configured to measure an amount of forward power of the electromagnetic wave passing through the enclosure toward the second waveguide and a second sensor configured to measure an amount of reverse power passing through the enclosure toward the mm wave emitter.

Aspects of the example system, which can be combined with the example system alone or in combination with other aspects, can include the following. A plasma trap is configured to direct plasma away from the mm wave emitter.

Aspects of the example system, which can be combined with the example system alone or in combination with other aspects, can include the following. The plasma trap includes at least one of the following. An electromagnet, a permanent magnet, A cavity of sufficient size to reduce the flow of plasma, or a gas flow port arranged to direct plasma away from the mm wave emitter when gas is flowing through the gas flow port.

Aspects of the example system, which can be combined with the example system alone or in combination with other aspects, can include the following. The at least one arc detector includes a first arc detector configured to detect a first arc event associated with at least one component of the set of components, and/or a second arc detector that is configured to detect a second arc event as a transient arc from the second waveguide.

Aspects of the example system, which can be combined with the example system alone or in combination with other aspects, can include the following. The first port is configured to receive the gas from a gas source and to direct the gas into the borehole as purge gas.

Aspects of the example system, which can be combined with the example system alone or in combination with other aspects, can include the following. The purge gas is configured follow a flow passage into the borehole, the purge gas configured to cool a downhole end of the flow passage, cool the downhole end of the flow passage, and carry cuttings up an annulus defined by the flow passage and the borehole.

Aspects of the example system, which can be combined with the example system alone or in combination with other aspects, can include the following. The enclosure further includes a second port coupled to a pressure relief valve.

Aspects of the example system, which can be combined with the example system alone or in combination with other aspects, can include the following. The enclosure includes a coating on an inner surfaces thereof. The coating is configured to absorb scatted electromagnetic radiation reflected from the borehole.

Aspects of the example system, which can be combined with the example system alone or in combination with other aspects, can include the following. The enclosure includes a flow passage defined by a conduit of polytetrafluoroethylene (PTFE). The flow passage is configured to direct water through the enclosure. The water is configured to carry excess power from the enclosure.

Aspects of the example system, which can be combined with the example system alone or in combination with other aspects, can include the following. One or more of the first set of waveguides include a cooling mechanism on an exterior surface thereof. The cooling mechanism is configured to remove heat generated in the transmission of the electromagnetic wave.

Aspects of the example system, which can be combined with the example system alone or in combination with other aspects, can include the following. The cooling mechanism includes fans.

Aspects of the example system, which can be combined with the example system alone or in combination with other aspects, can include the following. The cooling mechanism includes radiant fins.

Aspects of the example system, which can be combined with the example system alone or in combination with other aspects, can include the following. The cooling mechanism includes one or more water conduits arranged adjacent to the exterior surface of the first set of waveguides.

Aspects of the example system, which can be combined with the example system alone or in combination with other aspects, can include the following. The water conduits include copper tubing.

Aspects of the example system, which can be combined with the example system alone or in combination with other aspects, can include the following. A multi-port waveguide includes multiple radially positioned ports arranged to selectively provide the electromagnetic wave in one or more modes to the first set of waveguides. At least one of the radially positioned ports is configured to convey data cables, liquids, or additives into the borehole.

Aspects of the example system, which can be combined with the example system alone or in combination with other aspects, can include the following. The data cables include a fiber optic cable configured to convey at least one of acoustic data, temperature data, downhole waveguide strain, stand-off distance, or pressure data from the borehole.

Aspects of the example system, which can be combined with the example system alone or in combination with other aspects, can include the following. The second waveguide is configured to translate into or out of the borehole along a stroke length.

Aspects of the example system, which can be combined with the example system alone or in combination with other aspects, can include the following. An electrical breaker is positioned between the mm wave emitter and the first set of waveguides. The electrical breaker is configured to electrically isolate the mm wave emitter from the first set of waveguides.

Aspects of the example system, which can be combined with the example system alone or in combination with other aspects, can include the following. A matching optics unit (MOU) is positioned between the mm wave emitter and a first waveguide of the first set of waveguides. The MOU is configured to align the electromagnetic wave emitted from the mm wave emitter with an axis extending through the first waveguide of the first set of waveguides.

Aspects of the example system, which can be combined with the example system alone or in combination with other aspects, can include the following. an electrical breaker positioned between the mm wave emitter and a first waveguide of the first set of waveguides, the electrical breaker configured to galvanically isolate the mm wave emitter from the first set of waveguides.

Aspects of the example system, which can be combined with the example system alone or in combination with other aspects, can include the following. At least one waveguide of the first set of waveguides includes an expansion joint configured to expand or contact responsive to thermal expansion or contraction of the at least one waveguide.

Aspects of the example system, which can be combined with the example system alone or in combination with other aspects, can include the following. The first set of waveguides further includes a reflected power management device (RPMD) coupling two waveguides of the set of waveguides. The RPMD is configured to direct electromagnetic radiation reflected from the borehole away from the mm wave emitter.

Aspects of the example system, which can be combined with the example system alone or in combination with other aspects, can include the following. The RPMD comprises a plate defining an orifice. The plate is angled relative to the transmission axis of the first set of waveguides. The RPMD further includes wires extending across the orifice.

Aspects of the example system, which can be combined with the example system alone or in combination with other aspects, can include the following. A combiner unit is configured to couple a second mm wave emitter emitting a second electromagnetic wave in the first mode.

Aspects of the example system, which can be combined with the example system alone or in combination with other aspects, can include the following. The second mm wave emitter is configured to emit the second electromagnetic wave with a frequency different from the first electromagnetic wave.

Aspects of the example system, which can be combined with the example system alone or in combination with other aspects, can include the following. The second mm wave emitter is configured to emit the second electromagnetic wave with a polarization different from the first electromagnetic wave.

An example implementation of the subject matter described within this disclosure is an apparatus with the following features. An enclosure is configured to receive an electromagnetic wave from a mm wave emitter by a first waveguide positioned between the mm wave emitter and the enclosure. The enclosure includes components configured to manage transmission of the electromagnetic wave to a second waveguide positioned relative to a borehole of a well to be formed via the electromagnetic wave transmitted through the second waveguide. The components include at least one of the following features. A first port at which a gas is received can be included. At least one mirror configured to adjust a direction or a diameter of the electromagnetic wave provided to the second waveguide can be included. A frequency sensor configured to sample the electromagnetic wave can be included. At least one power measurement sensor configured to measure a power of the electromagnetic wave can be included. At least one arc detector configured to detect an arc event responsive to transmitting the electromagnetic wave to the second waveguide can be included. A cooled wire grid configured to direct electromagnetic radiation in the first mode reflected from the borehole away from the mm wave emitter can be included. A load cell provided on an exterior surface of the enclosure can be excluded. A barrier window can be included.

An example implementation of the subject matter described within this disclosure is a system with the following features. a millimeter (mm) wave emitter is configured to emit an electromagnetic wave in a first mode. A free space transmission system includes at least one curved mirror arranged to refocus and redirect the electromagnetic wave towards an enclosure configured to receive the electromagnetic wave from the free space transmission system. The enclosure includes components configured to manage transmission of the electromagnetic wave in the first mode to a waveguide positioned relative to a borehole of a well to be formed via the electromagnetic wave transmitted through the waveguide. The components include at least one of the following features. A first port at which a gas is received can be included. At least one mirror configured to adjust a direction or a diameter of the electromagnetic wave provided to the waveguide can be included. A frequency sensor configured to sample the electromagnetic wave can be included. At least one power measurement sensor configured to measure a power of the electromagnetic wave can be included. At least one arc detector configured to detect an arc event responsive to transmitting the electromagnetic wave to the second waveguide can be included. A cooled wire grid configured to direct electromagnetic radiation in the first mode reflected from the borehole away from the mm wave emitter can be included. A load cell provided on an exterior surface of the enclosure can be included.

### DESCRIPTION OF DRAWINGS

These and other features will be more readily understood from the following detailed description taken in conjunction with the accompanying drawings, in which:

FIG. 1 is a diagram illustrating an exemplary embodiment of a millimeter wave drilling system including a multi-piece corrugated waveguide as described herein;

FIG. 2 is a diagram illustrating a cross sectional view of a borehole including a waveguide for low loss transmission of millimeter wave radiation as described herein;

FIG. 3 is a schematic diagram illustrating a topside millimeter wave drilling system with integrated components;

FIGS. 4A-4B are diagrams illustrating cross-sectional views of exemplary implementations of a multi-piece corrugated waveguide including a casing from which the tube and coil spring can extend as described herein;

FIGS. 5A-5B are perspective views of example telescoping waveguides that can be used with aspects of this disclosure;

FIG. 6 is a three-quarter cross-sectional view of an example window assembly that can be used with aspects of this disclosure;

FIG. 6A is a schematic diagram of a free space transmission system;

FIG. 6B is a schematic diagram of a hybrid transmission system;

FIG. 7 is a side-cross sectional view of an example integrated transmission head that can be used with aspects of this disclosure;

FIG. 8 is a perspective view of example internal wave directing geometry of the transmission head illustrated in FIG. 7;

FIG. 9 is a perspective view of the integrated transmission head with cooling components attached;

FIG. 10 is a schematic diagram of an example sensing arrangement that can be incorporated into the transmission head;

FIG. 11 is a schematic diagram illustrating a topside millimeter wave drilling system with integrated components;

FIG. 12 is a cross-sectional diagram of an example multi-piece corrugated waveguide including a bent tube as described herein;

FIG. 13 is a side cross-sectional view of an example taper section of a waveguide that can be used with aspects of this disclosure;

FIG. 14 is an example isolator that can be used with aspects of this disclosure;

FIG. 15 is a schematic diagram illustrating a topside millimeter wave drilling system with integrated components that includes two gyrotrons;

FIG. 16 is an example Quasi-Optic EM combiner that can be used with aspects of this disclosure;

FIG. 16A is a schematic diagram of a schematic diagram of an example electromagnetic beam splitter;

FIG. 16B is a cross-sectional diagram of an example transmission head that includes an electromagnetic beam splitter;

FIG. 16C illustrates an example diffraction grating;

FIG. 17 illustrates a multi-port waveguide in a variety of positions; and

FIGS. 18A-18B are schematic diagrams of a pressure relief system in various states of operation.

It is noted that the drawings are not necessarily to scale. The drawings are intended to depict only typical aspects of the subject matter disclosed herein, and therefore should not be considered as limiting the scope of the disclosure.

### DETAILED DESCRIPTION

A waveguide is a structure that guides waves, such as electromagnetic waves or sound, with minimal loss of energy by restricting the transmission of energy to one direction. Waveguides can be employed, for example, in millimeter wave drilling operations, to efficiently convey electromagnetic waves to depths necessary to form a well. The design and materials used to form the waveguide can affect the transmission efficiency of the electromagnetic waves transmitted in a particular transmission mode. For example, electromagnetic (EM) waves can be transmitted over long distances using a waveguide including a series of corrugated features. The corrugated features can include a pattern of repeating ridges or grooves that can extend within a length of a tube. The pattern of corrugated features (e.g., ridges, grooves, or the like) can be shaped to aid the propagation of the electromagnetic wave and can be dimensioned according to the properties (e.g., frequency) of the wave that the waveguide is designed to efficiently propagate. Often, corrugated waveguides can include a dielectric or conductive coating that can improve the transmission efficiency of the waveguide.

Drilling operations, whether they include millimeter wave drilling or conventional drilling, involve accommodating various geologic properties and contaminants. For example, porosity, liquid content, and hardness can all impact types of drill bits used and/or intensity of EM energy used during drilling operations. Similarly, drilling operations can result in unexpected “kicks” of high pressure gas or liquid. Protection and monitoring systems to accommodate such situations have bene developed, however, many such components, for protection, monitoring, and dealing with variable drilling operations are discrete, individual components that can take-up a large footprint at a drill site and can require separate and costly maintenance. As such, there is a need for an integrated component that can accommodate monitoring, protecting, and adjusting millimeter wave drilling operations.

The various implementations described herein can be employed in a variety of industries and applications wherein electromagnetic waves are transmitted, such as oil and gas production industry, nuclear energy, fusion reactors, drilling and mining operations, and sound or audio applications. The design and manufacturing approach of the dynamic waveguides can provide a less expensive alternative for any industry or application compared to purchasing multiple EM generator for multiple locations, or modifying existing structures to incorporate dedicated static waveguide systems. For dynamic operations within hazardous environments, some the dynamic waveguides described herein can also provide an option to keep an EM source in a safe environment and direct electromagnetic radiation to where it is needed within the hazardous environment instead of dynamically moving the EM source within the hazardous environment, reducing the probability of a spark or arc occurring.

In some implementations, the dynamic waveguide can be configured for use in millimeter wave drilling during formation of a wellbore. The transmission efficiency of some implementations of the dynamic waveguides described herein can also be improved by dimensioning features of internal geometry in regard to a particular transmission mode. Some implementations of the dynamic waveguides described herein can provide efficient transmission of electromagnetic waves in a variety of transmission modes.

Some implementations of the systems described herein can be formed by assembling multiple individual components. In some implementations, each of the individual components can be formed with greater precision, compared to existing methods of machining corrugation features within single, long pieces of tube. Forming components individually can ensure that the corrugation features have been formed with the desired properties necessary for efficient and frequency dependent electromagnetic wave transmission. And individually manufacturing components of some implementations of the multi-piece corrugated waveguide described herein can reduce operating and maintenance costs because the coil spring and tube can be assembled together in a greater range of transmission lengths compared to machining fixed lengths of tube.

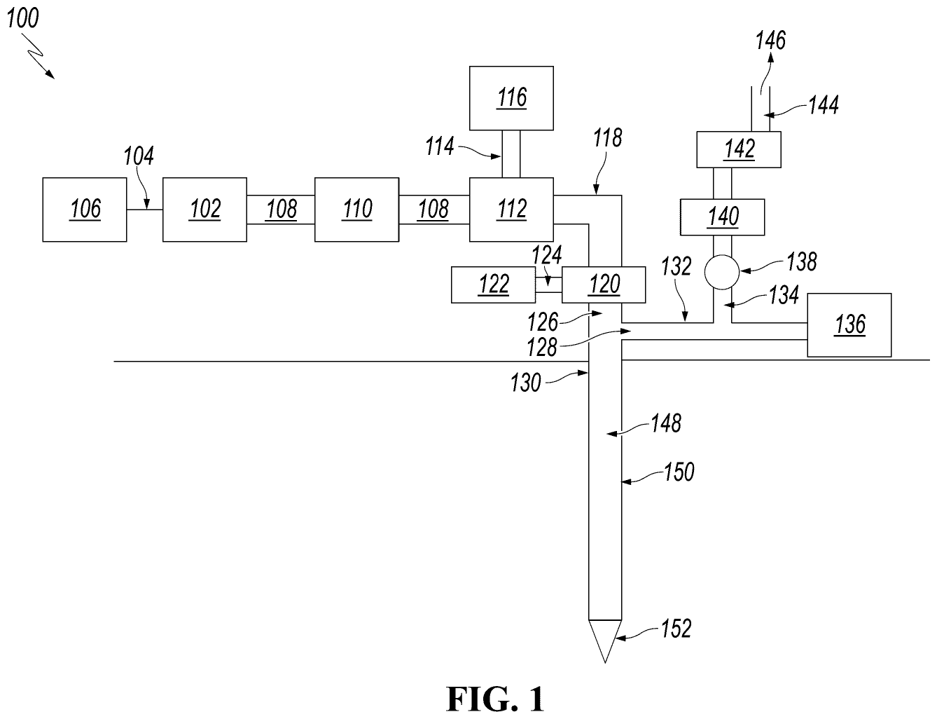

FIG. 1 is a diagram illustrating an exemplary implementation of a millimeter wave drilling (MMWD) system 100 including an example multi-piece waveguide 108. The MMWD system 100 shown in FIG. 1 includes a gyrotron 102 connected via power cable 104 to a power supply 106 supplying power to the gyrotron 102. While primarily described as using a gyrotron, other EM sources, such as a maser or other millimeter (mm) wave emitter can be used without departing from this disclosure. The high power millimeter wave beam output by the gyrotron 102 is guided by a waveguide 108, such as a dynamic waveguide described herein. While primarily described throughout this disclosure as pertaining to millimeter wavelength energies, the subject matter described herein can be applied to other wavelengths without departing from this disclosure. The waveguide 108 can include a waveguide bend 118, a window 120, a waveguide section 126 with opening 128 for off gas emission and pressure control. A section of the waveguide is below ground 130 to help seal the borehole 148.

As part of the waveguide 108 transmission line there is an isolator 110 to prevent reflected power from returning to the gyrotron 102 and an interface for diagnostic access 112. The diagnostic access is connected to diagnostics electronics and data acquisition 116 by low power waveguide 114. At the window 120 there is a pressurized gas supply unit 122 connected by plumbing 124 to the window to inject a clean gas flow across the inside window surface to prevent window deposits. A second pressurization unit 136 is connected by plumbing 132 to the waveguide opening 128 to help control the pressure in the borehole 148 and to introduce and remove borehole gases as needed. The window gas injection unit 122 can be operated at slightly higher pressure relative to the borehole pressure unit 136 to maintain a gas flow across the window surface. A branch line 134 in the borehole pressurization plumbing 132 can be connected to a pressure relief valve 138 to allow exhaust of volatized borehole material and window gas through a gas analysis monitoring unit 140 followed by a gas filter 142 and exhaust duct 144 into the atmosphere 146. In some implementations, the exhaust duct 144 can return the gas to the pressurization unit 136 for reuse.

Pressure in the borehole can be increased in part or in whole by the partial volatilization of the subsurface material being melted. A thermal melt front 152 at the end of the borehole 148 can be propagated into the subsurface strata under the combined action of the millimeter wave power and gas pressure leaving behind a ceramic (e.g., glassy) borehole wall 150. This wall can act as a dielectric waveguide to transmit the millimeter wave beam to the thermal front 152.

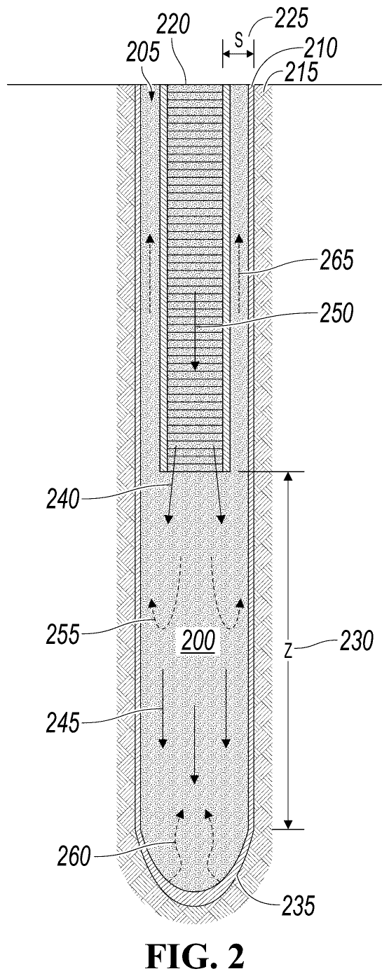

FIG. 2 is a diagram illustrating a cross sectional view of an example borehole including a multi-piece corrugated waveguide, which can be configured for low loss transmission of millimeter wave radiation. FIG. 2 provides a more detailed view of MMWD and corresponds to the MMWD system described in U.S. Pat. No. 8,393,410 to Woskov et. al, entitled “Millimeter-wave Drilling System.” The borehole 200 with annulus 205, glassy/ceramic wall 210 and permeated glass 215 has a waveguide assembly 220 inserted to improve the efficiency of millimeter wave beam propagation. In some implementations, the waveguide assembly can include a multi-piece corrugated waveguide that can be assembled sequentially in sections as the borehole 148 is formed. In some implementations, multiple waveguide assemblies can be inserted into the borehole. For example, multiple waveguide assemblies can be stacked upon one another to a distance of 1 km, 5 km, 10 km or more below a surface of a well.

As shown in FIG. 2, the diameter of the waveguide assembly 220 can be smaller than the borehole diameter to create an annular gap 225 for exhaust/extraction. The standoff distance 230 of the leading edge of the multi-piece corrugated waveguide 220 from the thermal melt front 235 of the borehole is far enough to allow the launched millimeter wave beam divergence 240 to fill 245 the dielectric borehole 200 with the guided millimeter-wave beam. The standoff distance 230 is also far enough to keep the temperature at the waveguide assembly 220 low enough for survivability. The inserted waveguide assembly 220 also acts as a conduit for a pressurized gas flow 250 from the surface. This gas flow keeps the waveguide clean and contributes to the extraction/displacement of the rock material from the bore hole. The gas flow 250 from the surface mixes 255 with the volatilized out gassing of the rock material 260 to carry the condensing rock vapor to the surface through annular space 225. The exhaust gas flow 265 is sufficiently large to limit the size of the volatilized rock fine particulates and to carry them all the way to the surface.

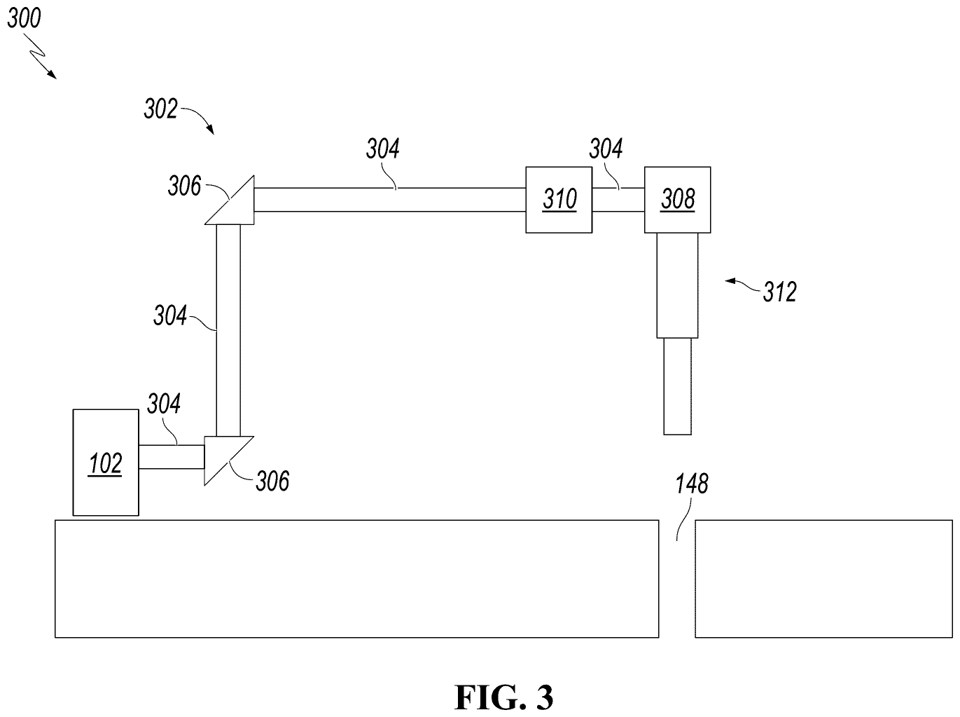

In some implementations, the components of the system 100 can be integrated and combined as to have fewer components within the wave passage. An example of such a system 300 is illustrated in FIG. 3. As shown in FIG. 3, the gyrotron 102 is arranged and configured to emit an electromagnetic wave in a first mode. In some implementations, the first mode is an HE₁₁ mode. The gyrotron 102 is coupled to emit the electromagnetic wave into a set of waveguides 302 that can include linear waveguides 304 and miter bends 306.

In some implementations, at least one miter bend 306 includes a mirror with a diffraction grating on a surface of the mirror. The diffraction grating is configured to direct electromagnetic radiation reflected from the borehole 148 away from the gyrotron 102, acting as a sort of check-valve for the electromagnetic wave. Alternatively or in addition, the enclosure of the transmission head 308 can include such a diffraction grating. In some implementations, such a diffraction grating can work based on higher order mode scattering.

In some implementations, the linear waveguides 304 and/or the miter bends 306 include a corrugation features on an inner surface. The corrugation features are configured to maintain the electromagnetic wave in the first mode as the electromagnetic wave propagates through the linear waveguides 304 and/or the miter bends 306. Alternatively or in addition, some of the corrugation features can be configured to convert the first mode of the electromagnetic wave to a second mode different than the first mode, for example, HE₁₁ TEₘₙ, TEM₀₀, or other higher order modes.

An a transmission head 308, defining an enclosure, at an end of the set of waveguides 302 is configured to receive the electromagnetic wave from the gyrotron 102. In some implementations, a barrier window 310 is positioned between the transmission head 308 and a miter bend 306. In some implementations, the barrier window can act as the window 120 previously described. The barrier window 310 is configured to protect the gyrotron from pressure values outside of the allowable pressure of the gyrotron 102. Such pressures can include a vacuum force or a positive pressure force. Examples of the barrier window 310 are described throughout this disclosure. In some implementations, the barrier window 310 is integrated into the transmission head 308.

The enclosure, sometimes called a transmission head 308, can include multiple components, some of which were described in relation to FIG. 1, configured to manage transmission of the electromagnetic wave, in the first mode, to a second waveguide 312. The second waveguide 312 is arranged to emit the electromagnetic wave towards a present or future borehole, for example, for a well. The second waveguide 312, in some implementations, can be an extendable waveguide. Examples of such a waveguide are described throughout this disclosure. In implementations that use an extendable waveguide, the wave guide is able to actuate, or stroke, a length. In some implementations, this can be at least a length of sections of downhole waveguide 220. This allows the space for the downhole waveguide sections to be inserted into the hole, penetrate a depth of approximately a length of the section, and receive a new section. To receive a new section, the extendable waveguide is moved into a retractable position. As the borehole 148 is formed and deepened, the extendable waveguide moves towards an extended position. The second waveguide 312 in the presently illustrated implementation includes an extendable waveguide in an extended position.

The waveguides described throughout this disclosure can include a coating on inner surfaces thereof. Such a coating can be configured to absorb scattered electromagnetic radiation generated in the transmission of the electromagnetic wave, for example during transmission from the transmission head 308 into the second waveguide 312.

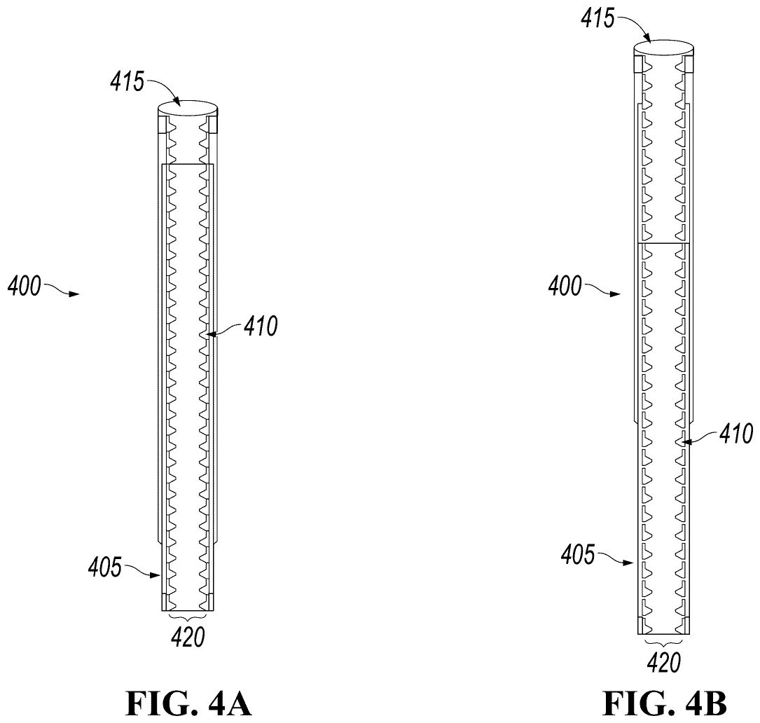

FIGS. 4A-4B are diagrams illustrating cross-sectional views of an example multi-piece corrugated waveguide (MCG) 400 including a casing from which the tube and coil spring can extend as described herein. In some implementations, the MCG 400 can act as the second waveguide 312. The MCG 400 can include a tube 405, a coil spring 410 within the tube 405, and a casing 415. As shown in FIG. 4A, the MCG 400 is shown in a retracted position. The tube 405 and the coil spring 410 are retracted within the casing 415. In FIG. 4B, the MCG 400 is shown in an extended position. In FIG. 4B, the tube 405 and the coil spring 410 have been extended from within the casing 415. In this way, the tube 405 and coil spring 410 can telescopically retract into and extend from the casing 415. By having the coiled spring 410 span the length of the casing 415 and the tube 405, the millimeter wave can be contained regardless of what a position or angle of flexion the MCG 400. Since the spring 410 is one piece, there is no step change between the inner diameter of the casing 415 and inner diameter of the tube 405. This reduces or eliminates loss of power of millimeter wave that can be associated with abrupt diameter changes.

In some implementations, the coil spring 410 can include an inner diameter 420 measured between protruding portions of each coil element of the coil spring 410. In some implementations, the inner diameter 1420 can include a diameter of 5.0 mm-15.0 mm, 10.0 mm-20.0 mm, 15.0 mm-25.0 mm, 20.0 mm-30.0 mm, 25.0 mm-35.0 mm, 30.0 mm-40.0 mm, 45.0 mm-55.0 mm, 50.0 mm-60.0 mm, 55.0 mm-65.0 mm, 60.0 mm-70.0 mm, 65.0 mm-75.0 mm, 70.0 mm-80.0 mm, 75.0 mm-90.0 mm, or 85.0 mm-200.0 mm. In some implementations, the diameter can be greater than 200.0 mm or less than 5.0 mm. Other diameters are possible. In some implementations, the inner diameter 1420 can include a tolerance range, such as +/−0.075 mm, +/−0.1 mm, +/−0.125 mm, +/−0.150 mm, +/−0.175 mm, +/−0.2 mm, +/−0.225 mm, or +/−0.25 mm, although other tolerance ranges are possible.

Alternatively or in addition, the second waveguide 312 can include a standard corrugated waveguide, a smooth waveguide, or any other style linear waveguide that is appropriate for the transmission mode being directed into the borehole 148.

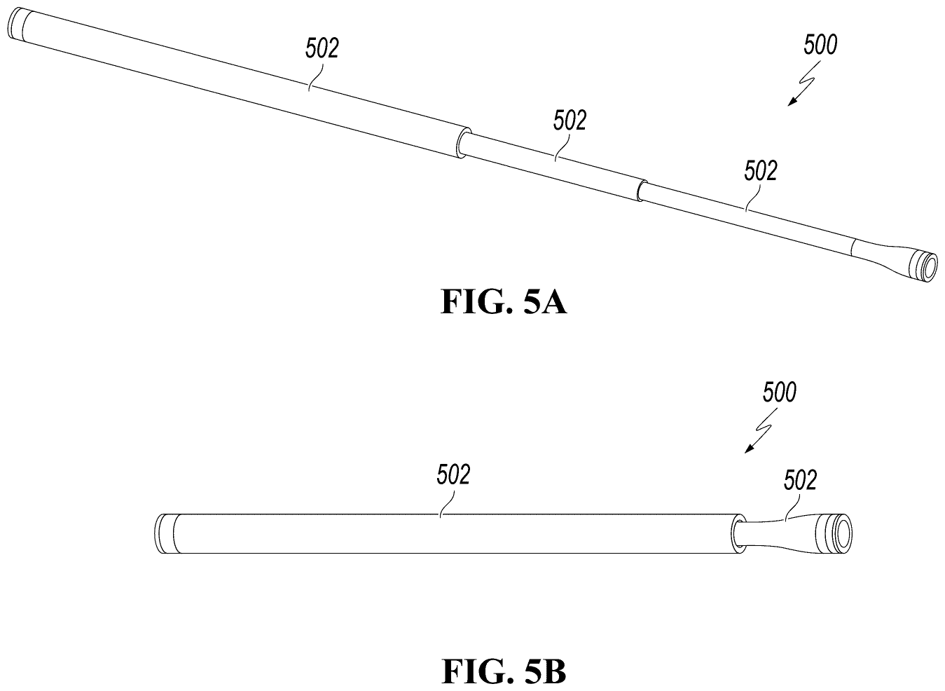

FIGS. 5A-5B are perspective views of example a telescoping waveguide 500 that can be used with aspects of this disclosure. FIG. 5A shows the telescoping waveguide 500 in an extended position, and FIG. 5B shows the telescoping waveguide 500 in a collapsed position. In some implementations, the telescoping waveguide 500 can have internal components similar to those described in regard to the corrugated waveguide 400 previously described. In general, the telescoping waveguide 500 has multiple linear waveguide sections 502 of progressively smaller outer diameters such that the smaller diameter sections 502 can coaxially slide into and nest within the larger diameter sections. While the illustrated implementation of the telescoping waveguide 500 includes three sections 502, greater or fewer sections 502 can be used. For example, two sections 502, four sections 502, five sections 502, or six sections 502 can be used. A stroke length of the telescoping waveguide corresponds to a length of each of the sections 502 and a number of the sections 502.

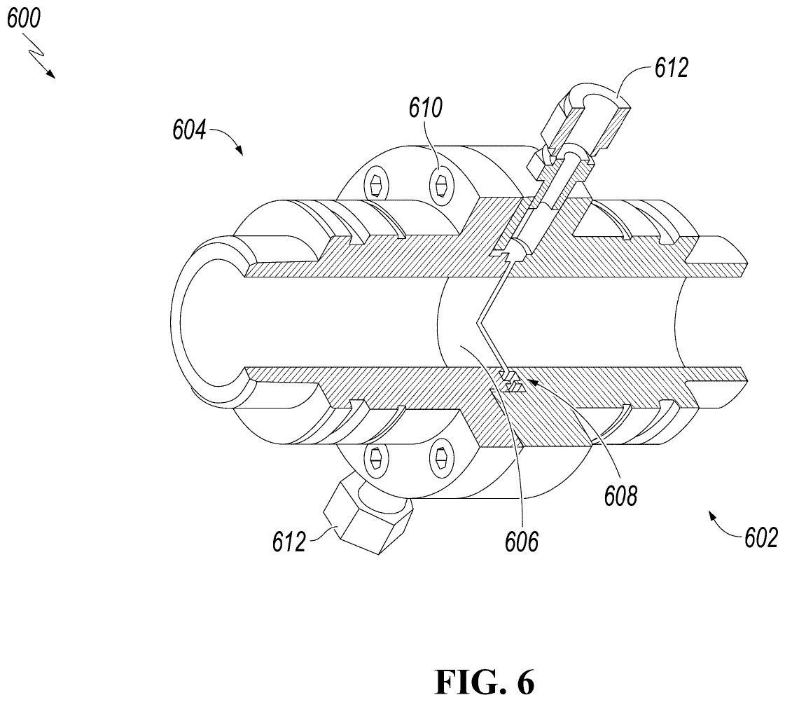

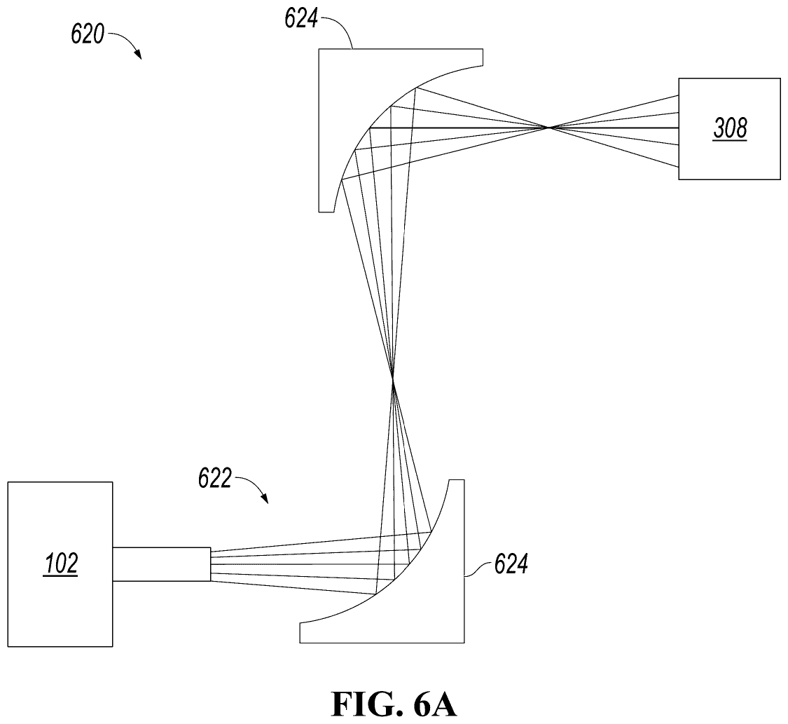

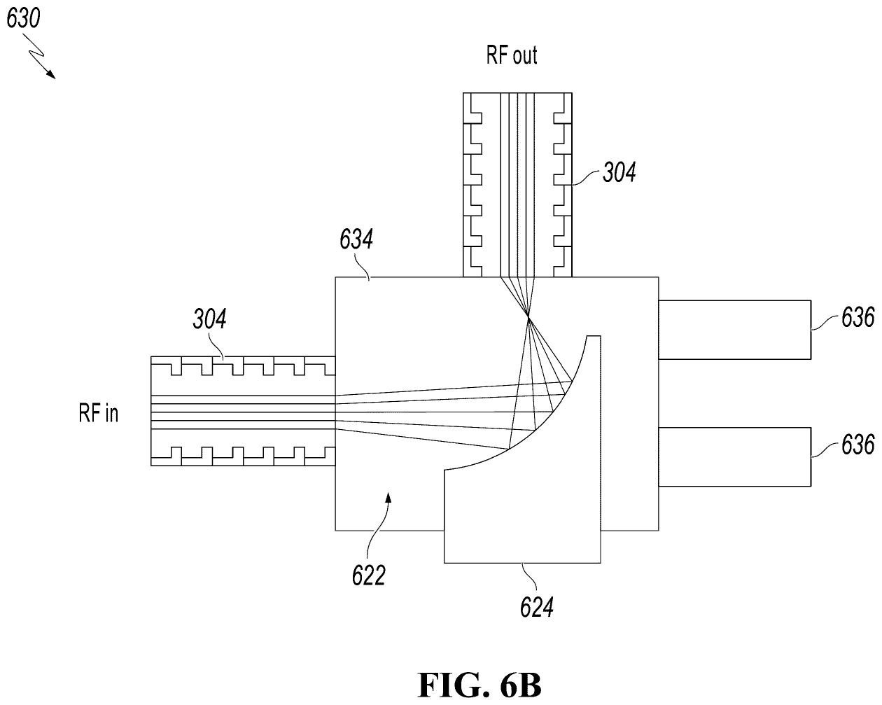

FIG. 6 is a three-quarter cross-sectional view of an example window assembly 600 that can be used as barrier window 310 and window 120 previously described. The window assembly 600 includes an upstream section 602 and a downstream section 604. Between the upstream section 602 and the downstream section 604 is a window 606 made of a material transparent to the wavelength of the electromagnetic wave being transmitted. For example, in millimeter wave applications, the window 606 can be made of synthetic diamond or sapphire. In addition, the window 606 is made of a material and/or has a geometry (e.g. thickness) to withstand a specified pressure differential across both sides of the window 606. The window 606 itself is secured in place by compression of seals 608 on either side of the window 606 the seals are compressed by fasteners 610 that secure the upstream section 602 and the downstream section 604 together. In some implementations, on or more ports 612 can be included. Such ports 612 can be fluidically connected to one or both sides of the window 606. The parts can be used to pass a coolant, such as water, across the window to keep the window 606 cool and reduce thermal stress. Alternatively on in addition, the ports 612 can be used to set a specified pressure differential or pressure differential range across the window 606. While described as its own discreet component, the window assembly 600, in some implementations, can be included within the transmission head 308.

In some implementations, such as the implementation illustrated in FIG. 6A, a free space transmission system 620 can be used. Typically, an electromagnetic wave 622 will diverge and spread after being emitted from the gyrotron 102. To correct for this, a curved mirror 624 is positioned to refocus and/or redirect the electromagnetic wave 622. As the electromagnetic wave 622 begins to diverge again, another curved mirror 624 can be used to re-focus and redirect the electromagnetic wave 622. This can be repeated as many times as necessary until the electromagnetic wave reaches the transmission head 308. In some implementations, a standard mirror can be used in the system 620. Such a mirror can be used to redirect the electromagnetic wave 622 without re-focusing the electromagnetic wave 622. In some implementations, the free space transmission system can be enclosed for safety.

In some embodiments, a hybrid system can be used. Such a system 630 is shown in FIG. 6B. The system 630 can be used in lieu of the miter bend 306 previously described. In the illustrated implementation, a waveguide 304 directs the electromagnetic wave into a free space chamber 634, where the electromagnetic wave 622 begins to diverge. A curved mirror 624 then redirects and refocuses the electromagnetic wave 622 into a subsequent waveguide 304. In some implementations, the free space chamber 634 is evacuated and under vacuum using one of the ports 636. The free space chamber 634 is of sufficient size to allow the electromagnetic wave 622 to diverge. To refocus the electromagnetic wave 622 into the subsequent waveguide 304, the curved mirror 624 is configured to ensure a diameter of the electromagnetic wave 622 has a smaller diameter than the subsequent waveguide 304.

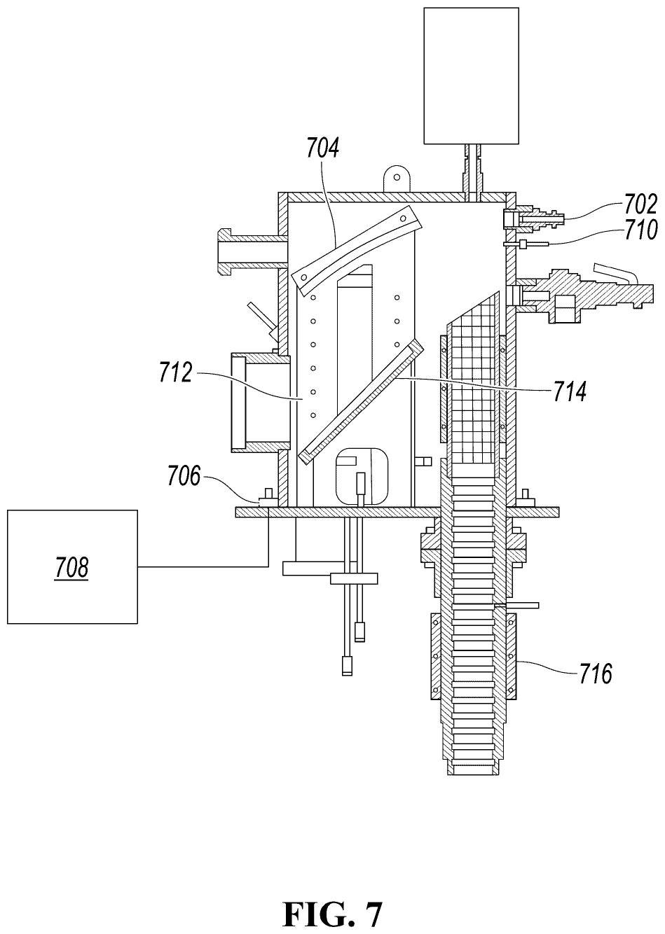

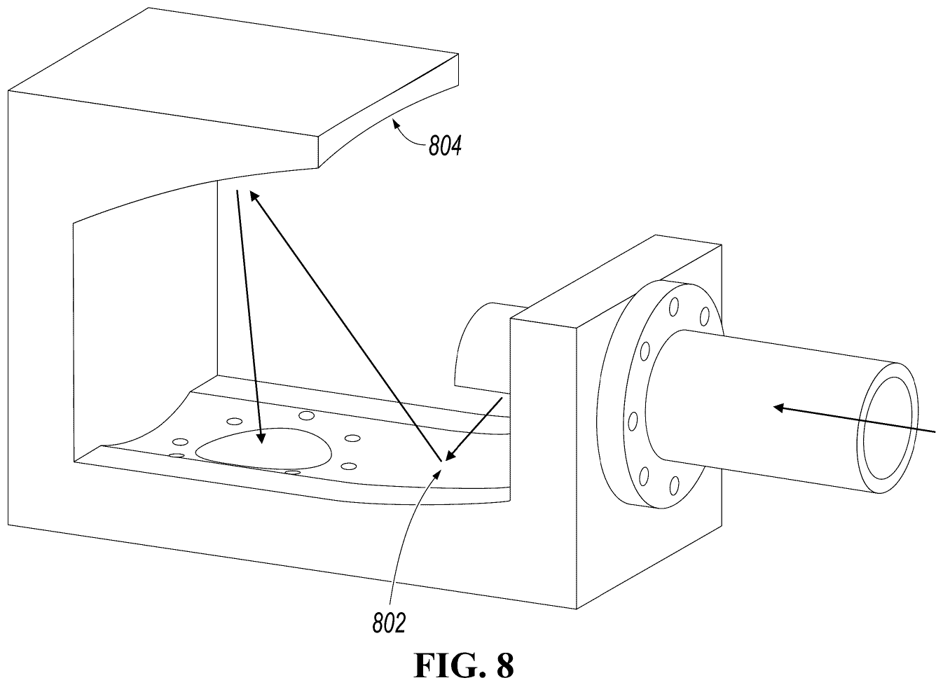

FIG. 7 is a side-cross sectional view of an example integrated transmission head 308 that can be used with aspects of this disclosure. The integrated transmission head 308 can include many of the components previously described within this disclosure. For example, the integrated transmission head 308 can include a gas injection port 702 to receive purge gas to keep the quasi-optical internal components of the integrated transmission head 308 clear of contaminants. Such quasi-optical components can include a focusing mirror 704 configured to adjust a direction or a diameter of the electromagnetic wave provided to the second waveguide 312. In some implementations, the focusing mirror 704 is a curved mirror, such as a parabolic mirror. Alternatively or in addition, the gas can be directed into the borehole 148 as purge gas to clear the downhole waveguide 220. In some implementations, the purge gas is configured to direct plasma emitted from the borehole 148 outside of the enclosure of the transmission head 308. Other plasma mitigation components, or traps, can be included without departing from this disclosure. For example, an electromagnet or a permanent magnet can be used to direct or retain any plasma formed. Alternatively or in addition, the integrated transmission head can define a cavity of sufficient size to allow the electromagnetic wave to diverge, reducing a likelihood of plasma formation. Additional ports can be included, for example, for the supply of vacuum or for pressure relief devices, such as a pressure release valve or a rupture disc.

Alternatively or in addition, the integrated transmission head 308 can include one or more sensors. For example, a frequency sensor 706 can be included to sample the electromagnetic wave. Such a sensor can be used to determine a health of the electromagnetic system, including waveguides and/or the gyrotron 102. For example, the frequency sensor 706 can, in some implementations or instances, be coupled to a computing device 708 configured to determine if a sampled frequency of the electromagnetic wave is within a predetermined range of values stored in a memory of the computing device 708.

Alternatively or in addition, an arc detector 710, configured to detect an arc event responsive to transmitting the electromagnetic wave through the transmission head 308 and/or the second waveguide, can be included. Arc events can cause damage to the electromagnetic systems described herein, and can be symptoms of other potential issues. In some implementations, multiple arc detectors can be used. For example, a first arc detector can be arranged and configured to detect an arc event associated with at least one of the components described herein, and/or a second arc detector cab be arranged and configured to detect a second arc event as a transient arc from the second waveguide 312.

In some implementations, a cooled wire grid 712 can be included and can be configured to direct electromagnetic radiation in the first mode reflected from the borehole 148 away from the gyrotron 102. In some implementations, such a cooled wire grid 712 can be incorporated as a discreet unit within the electromagnetic wave transmission passage. Such implementations are described throughout this disclosure. Alternatively or in addition, a load cell 716 can be provided on an exterior surface of the transmission head 308. Such a load cell 716 can be used to determine a weight of the transmission string (made up of downhole waveguide 220 sections) suspended within the borehole 148. Alternatively or in addition, the load cell 716 can be used to detect increase in friction, clogging of borehole, insufficient bore hole size, stick-slip, or getting stuck. Similarly, the load cell 716 can be used as a diagnostic tool to help get the second waveguide 312 unstuck or otherwise verify that a problem has been cleared to continue running second waveguide 312 into the borehole 148.

In some implementations, a power measurement sensor 714, configured to measure a power of the electromagnetic wave, can be included. Such a sensor 714 can be used for closed-loop control of the gyrotron 102 when a specified power level is required. Additional diagnostic devices and/or sensors can be included without departing from this disclosure. For example, a sampling device can be included to measure a temperature, a standoff, mode purity, plasma formation, and/or a geometry of the borehole.

As previously discussed, the transmission head 308 can include quasi-optical components to direct and/or manipulate the electromagnetic wave. Examples of such an arrangement are shown in FIG. 8. One or more focusing mirrors (802, 804) are configured to adjust the direction of the electromagnetic wave such that the electromagnetic wave provided to the second waveguide 312. While primarily illustrated and described throughout this disclosure as being used to form or extend a vertical borehole, horizontal or deviated boreholes can similarly be formed or extended using the subject matter described herein. In some implementations, the direction of the electromagnetic wave provided to the second waveguide is adjusted by a first focusing mirror 802 and a diameter of the electromagnetic wave provided to the second waveguide is adjusted by a second focusing mirror 804. Alternatively or in addition, greater or fewer parabolic mirrors can be used. In some implementations, one or more of the focusing mirrors are curved mirrors, such as parabolic mirrors.

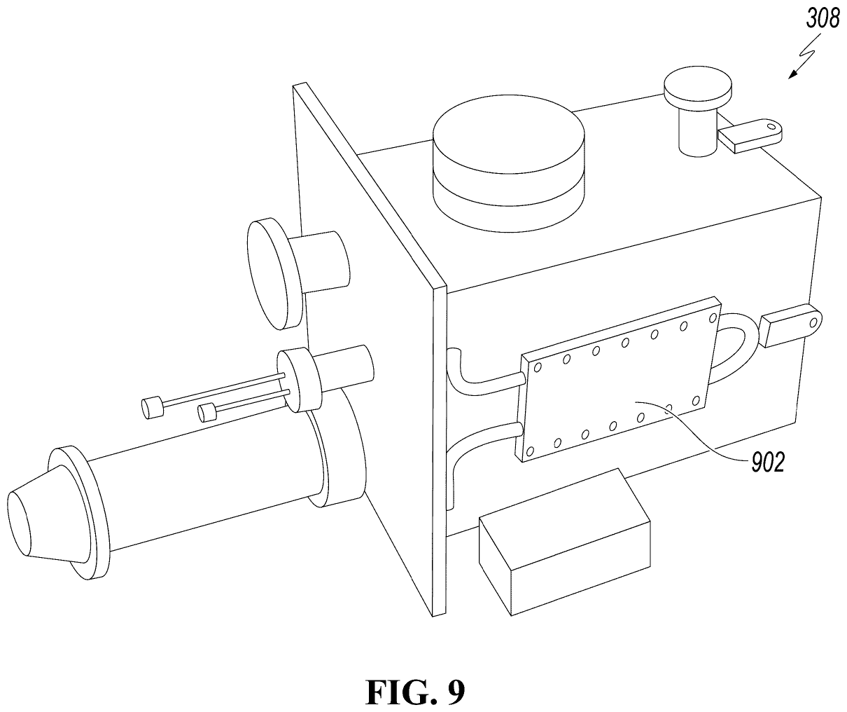

FIG. 9 is a perspective view of the integrated transmission head 308 with cooling components 902 attached. In some implementations, other components of the electromagnetic wave system 300 can include water cooling. For example, the first set of waveguides 302 and/or the second waveguide 312 can include a water cooling mechanism on an exterior surface. In such implementations, the water cooling mechanism 902 is configured to absorb heat generated in the transmission of the electromagnetic wave to the second waveguide 312. In some implementations, the water cooling mechanism includes one or more water conduits formed from copper tubing and arranged adjacent to the exterior surface of the first set of waveguides 302 or the second waveguide 312, and or the transmission head 308. Alternatively or in addition, the transmission head can internally include a flow passage defined by a conduit of polytetrafluoroethylene (PTFE). The flow passage is arranged to direct water through the enclosure within the transmission head 308 to carry excess power from the transmission head 308, for example, from reflected power from the borehole 148. While PTFE is an option for such an application, other materials transparent to the electromagnetic wave can be used without departing from this disclosure.

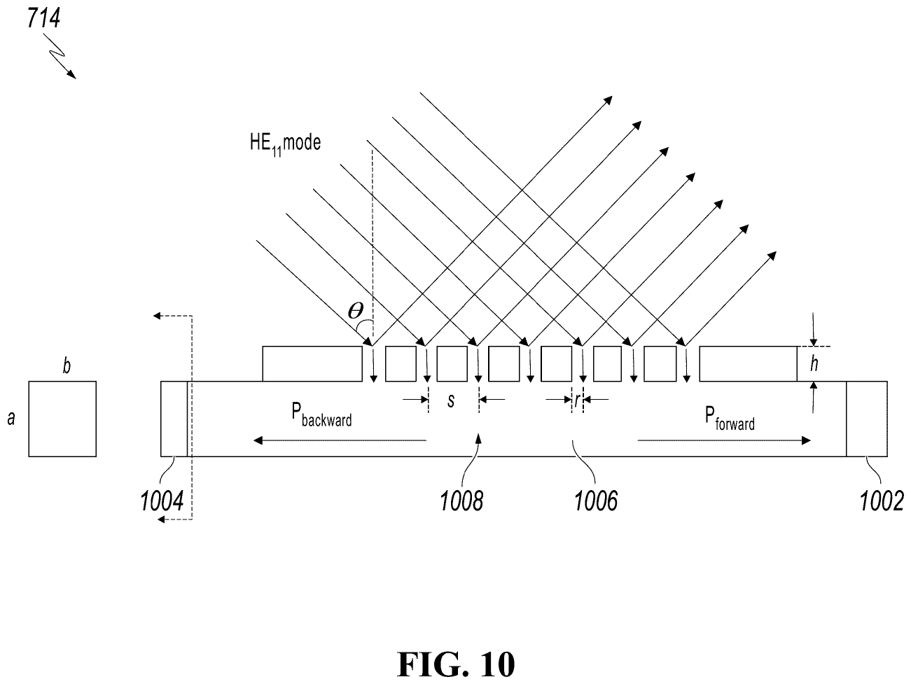

Returning to the power measurement sensor 714, FIG. 10 illustrates a schematic diagram of an example sensing arrangement that can be incorporated into the transmission head. More specifically, the power measurement sensor includes a first sensor 1002 configured to measure an amount of forward power of the electromagnetic wave passing through the enclosure toward the second waveguide, and a second sensor 1004 configured to measure an amount of reverse power passing through the enclosure toward the gyrotron 102. The sensors are positioned within a channel 1006 that runs substantially 45° to a direction of transmission of the electromagnetic wave. The channel 1006 is connected to the main transmission passage by perforations 1008 sized to allow both transmitted (forward) electromagnetic waves to enter and reflected (reverse) electromagnetic waves to enter. The channel then directs both the transmitted and reflected electromagnetic waves to their respective sensors.

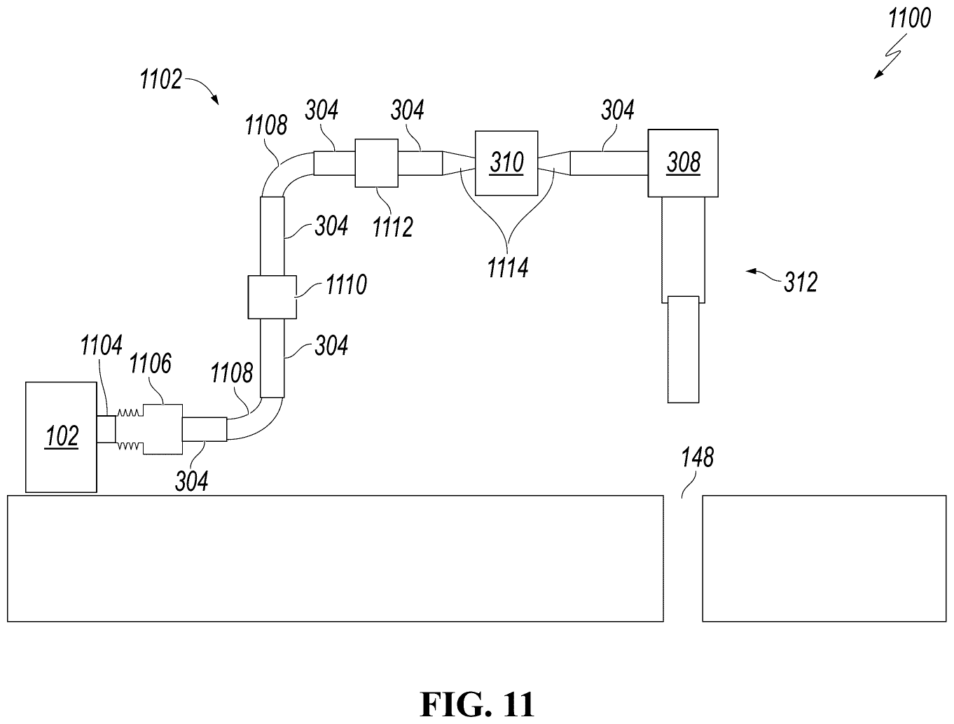

FIG. 11 is a schematic diagram illustrating a topside millimeter wave drilling system 1100 with integrated components. The system 1100 is substantially similar to the system 300 with the exception of any differences described herein. Between the gyrotron 102 and the set of waveguides 1102 is an electrical breaker 1104, or galvanic isolator, configured to electrically isolate the gyrotron from the set of waveguides 1102. The addition of the electrical breaker allows for accurate measurement of the body current of the gyrotron 102 to protect gyrotron 102. Immediately down-wave of the electrical breaker 1104 is a matching optics unit (MOU) 1106 configured to align the electromagnetic wave emitted from the gyrotron 102 with an axis extending through the first waveguide of the set of waveguides 1102. This additional alignment results in improved transmission efficiency through the waveguides 1102. To accomplish such feats, the electromagnetic wave passage defined by the MOU can include physical features, such as Dimples, ripples, curves, or other features appropriate for the intended application. In some implementations, additional components described in regards to the transmission head 308 can be incorporated into the MOU 1106, for example, a vacuum port, an arc detector, or a pressure safety device such as a pressure safety valve or rupture disc.

Instead of using miter bends 306, the system 1100 includes bends 1108 to change a direction of the electromagnetic wave passage. Examples of such bends are described throughout this disclosure. In some implementations, bends 1108 and miter bends 306 can both be included in an electromagnetic wave system. The bends 1108 can include a radius bend, a secant bend, or a varying radius bend without departing from this disclosure.

In some implementations, a waveguide of the set of waveguides 1102 includes an expansion joint 1110 configured to expand or contact responsive to thermal expansion or contraction of the at least one waveguide. Such an expansion joint can be structurally similar to the telescoping waveguide 500 or the MCG waveguide 400 previously described, though other expandable waveguides can be used without departing from this disclosure. In some instances, the expansion is on the order of inches.

In some implementations, a reflected power management device (RPMD) 1112 can be included and can couple two waveguides of the set waveguides 1102. The RPMD is configured to direct electromagnetic radiation reflected from the borehole away from the gyrotron 102. Examples of such an RPMD 1112 is described throughout this disclosure.

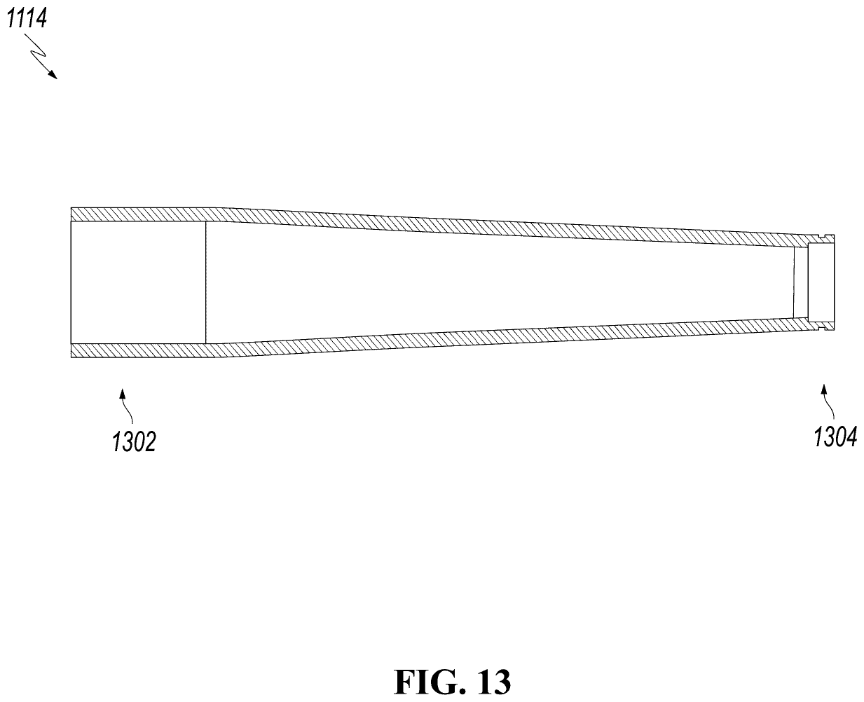

In some implementations, the set of waveguides 1102 and/or the second waveguide 312 can include one or more tapered portions 1114, such as the one illustrated in FIG. 13. The first end 1302 has a larger diameter than the second end 1304. The tapered portion 1114 can be used as an adapter to increase or decrease a diameter of the waveguide passage. In some implementations, such size adjustments can be used to change a transmission mode. In some implementations, such a size adjustment can be used to reduce a size, and therefore an expense, of certain components, for example, the window 606.

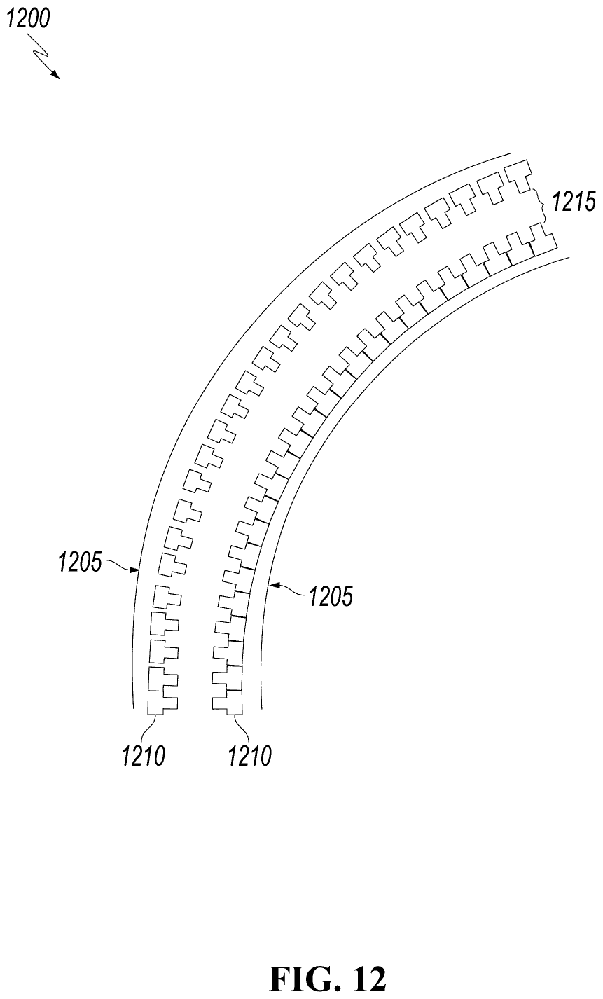

FIG. 12 is a diagram illustrating a cross-sectional view of an exemplary implementation of a multi-piece corrugated waveguide (MCG) 1200 including a bent tube as described herein. In some implementations, the MCG 1200 can be used as the bend 1108. As shown in FIG. 12, the MCG 1200 can include a tube 12012 (of which only the inner surface is shown for clarity) and a coil spring 1210 within the tube 12012. MCG 1200 can be deployed to maneuver or otherwise steer electromagnetic waves around topside obstacles which may otherwise limit the transmission efficiency of the transmitted electromagnetic waves. In some implementations, the tube 1205 can be a bellowed tube including a plurality of collapsible segments configured to form a bend in the tube 1205.

In some implementations, the coil spring 1210 can include an inner diameter 1215 measured between protruding portions of each coil element of the coil spring 1210. In some implementations, the inner diameter 1215 can include a diameter of 5.0 mm-15.0 mm, 10.0 mm-20.0 mm, 15.0 mm-25.0 mm, 20.0 mm-30.0 mm, 25.0 mm-35.0 mm, 30.0 mm-40.0 mm, 45.0 mm-55.0 mm, 50.0 mm-60.0 mm, 55.0 mm-65.0 mm, 60.0 mm-70.0 mm, 65.0 mm-75.0 mm, 70.0 mm-80.0 mm, 75.0 mm-90.0 mm, or 85.0 mm-200.0 mm. In some implementations, the diameter can be greater than 200.0 mm or less than 5.0 mm. Other diameters are possible. In some implementations, the inner diameter 515 can include a tolerance range, such as +/−0.075 mm, +/−0.1 mm, +/−0.125 mm, +/−0.150 mm, +/−0.175 mm, +/−0.2 mm, +/−0.225 mm, or +/−0.25 mm, although other tolerance ranges are possible.

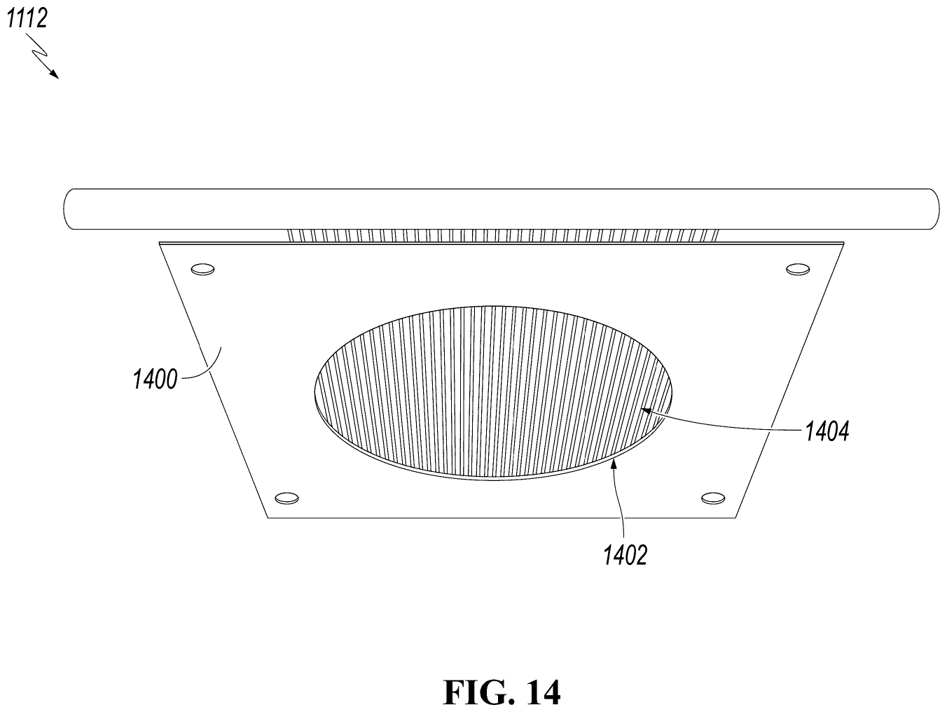

FIG. 14 is an example RPMD 1112, or isolator, that can be used with aspects of this disclosure. In some implementations, the RPMD 1112 can be used as the isolator 110. The RPMD 1112 includes a plate 1400 that is arranged within the waveguide at 45° to the travel direction of the electromagnetic wave. The plate 1400 defines an orifice 1402 with a wire grid 1404 extending across orifice 1402. The wire grid, in some implementations, can be convectively cooled, for example, by liquid nitrogen supplied across a surface of the wire grid 1404.

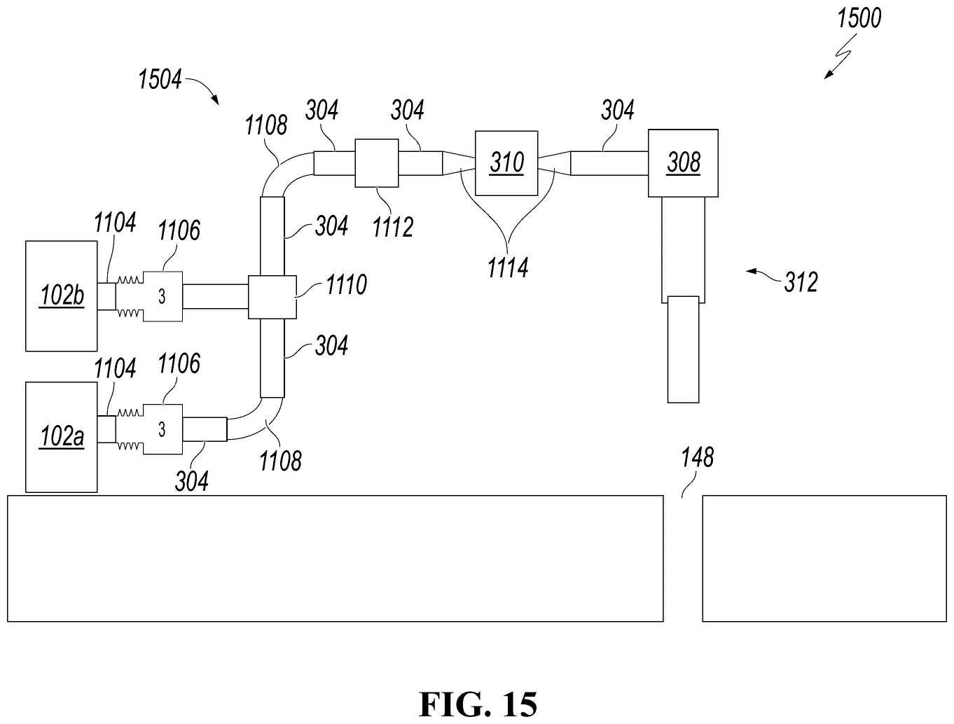

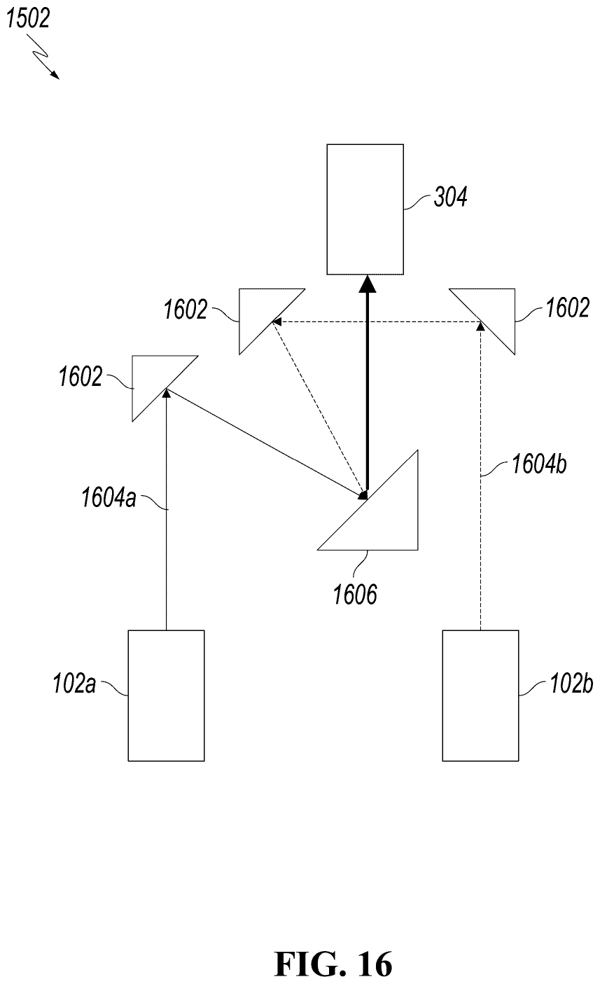

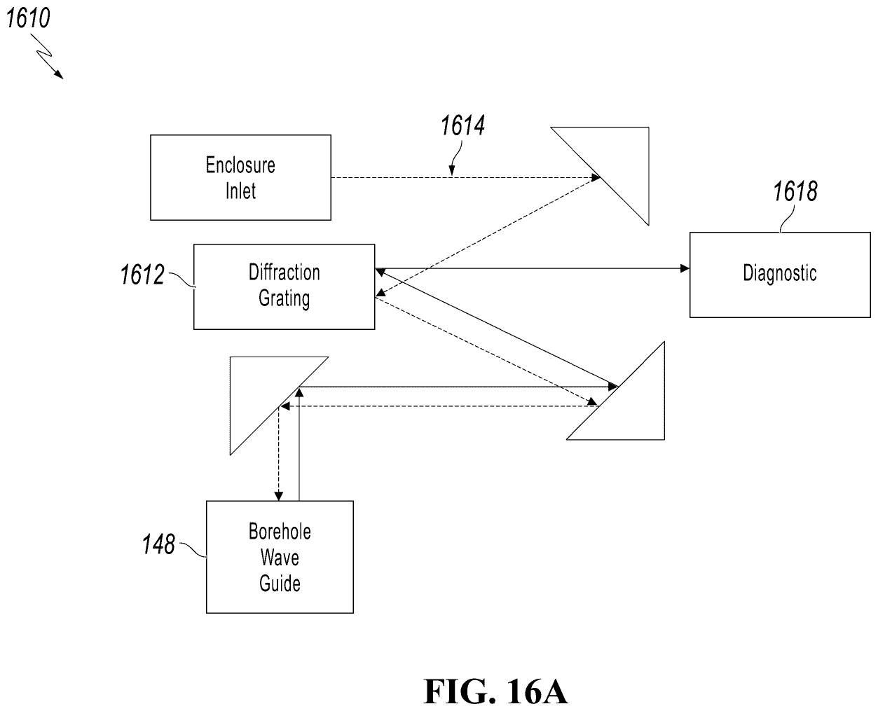

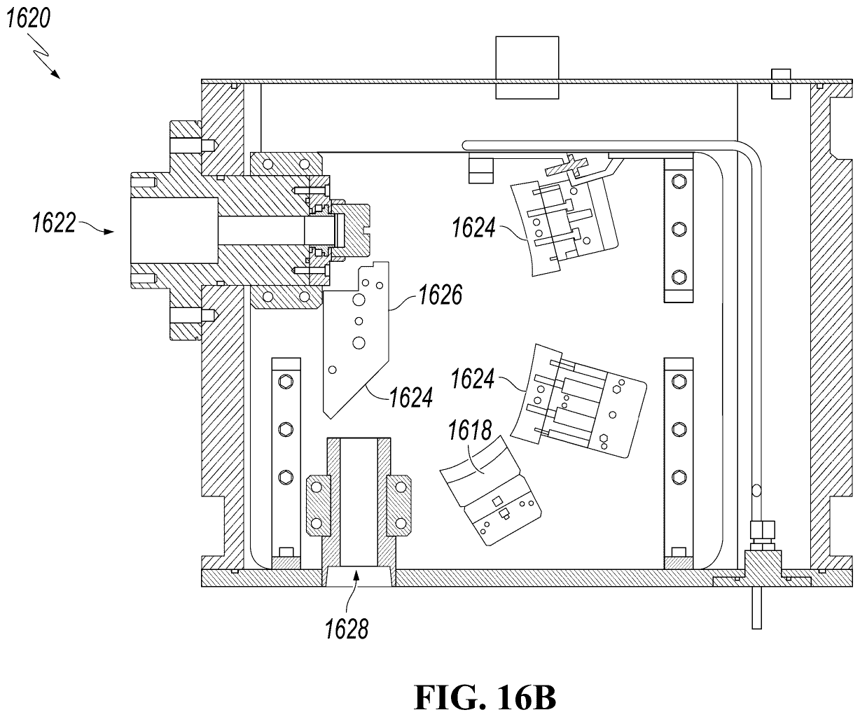

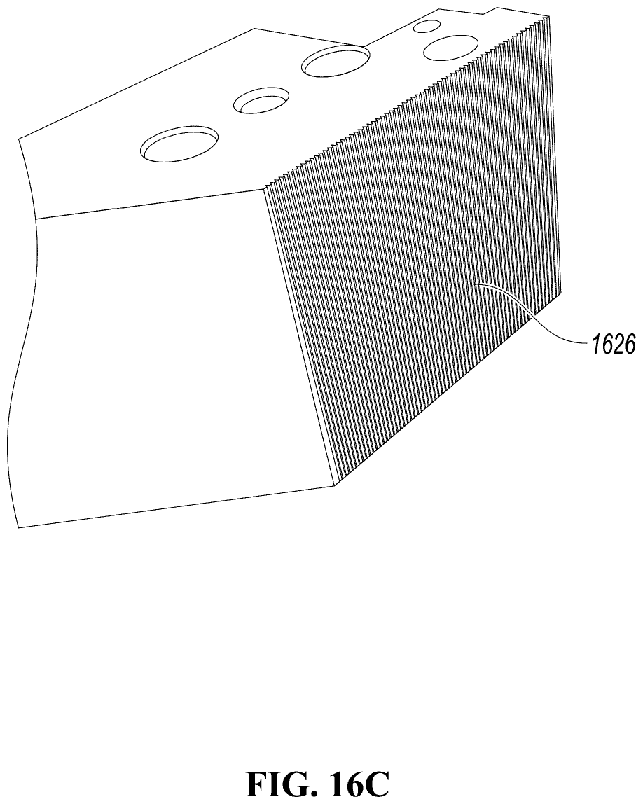

FIG. 15 is a schematic diagram illustrating a topside millimeter wave drilling system 1500 with integrated components that includes two gyrotrons 102. The system 1500 is substantially identical to system 1100 previously described with the exception of any differences described herein. As previously mentioned, the system 1400 includes a first gyrotron 102a and a second gyrotron 102b. The two gyrotrons (102a, 102b) can have a same power rating or different power ratings without departing from this disclosure. The electromagnetic waves from each gyrotron (102a, 102b) can be used by the system 1500 using a combiner unit 1502 configured to couple the first gyrotron 102a and the second gyrotron 102b to the set of waveguides 1504. An example of such a combiner unit 1502 is a Quasi-Optic EM combiner illustrated in FIG. 16. The combiner 1502 includes a series of mirrors 1602 or similar reflectors towards a combining mirror 1606. The combining mirror 1606 includes physical features (such as dimples or corrugation) to direct both a first electromagnetic wave 1604a and a second electromagnetic wave 1604b in a same direction down a waveguide 304, even if the first electromagnetic wave 1604a and the second electromagnetic wave 1604b impact the combining mirror 1606 at different angles. While primarily described as using the combining mirror 1606, other types of electromagnetic combiners can be used without departing from this disclosure, for example, prisms can be used with certain wavelengths. In some implementations, the first gyrotron 102a and the second gyrotron 102b emit electromagnetic waves of different modes. In some implementations, the first gyrotron 102a and the second gyrotron 102b emit electromagnetic waves of in the same mode. Mixing and matching of power levels, frequencies, polarizations, and modes can be performed with such an arrangement without departing from this disclosure.

Similar principles can be used to split an electromagnetic wave, for example, to pull a low-powered sample of the electromagnetic wave for diagnostic purposes. FIG. 16A shows such a system 1610. The illustrated splitter system 1610 includes a diffraction grating 1612 to pass electromagnetic waves at one frequency in one direction and deflect electromagnetic waves at another frequency towards another direction. As illustrated, the primary electromagnetic wave 1614 is directed through the system 1610 towards the borehole 148. A reflected electromagnetic wave 1616 entering the system from the borehole 148 is at a different frequency than the primary electromagnetic wave 1614. As such, the reflected electromagnetic wave 1616 can be deflected from the path of the primary electromagnetic wave 1614 with a diffraction grating 1612. Such a deflection can be used to direct the reflected electromagnetic wave 1616 towards a diagnostic system 1618.

This system 1610 can be incorporated into a transmission head 1620 illustrated in FIG. 16B. The transmission head 1620 can be used in place of transmission head 308 previously described. The transmission head 1620 is substantially similar too, and can include all of the features of, the transmission head 308 with the exception of any differences describe herein. The primary electromagnetic wave 1614 enters the transmission head through the inlet 1622. The electromagnetic wave 1614 is then directed by mirrors 1624 and the diffraction grating 1626 towards an outlet 1628 and the borehole 148. Any reflected electromagnetic waves 1616 that come back through the outlet 1628 are then directed to the diagnostic device 1618. FIG. 16C is a close view of the diffraction grating 1626.

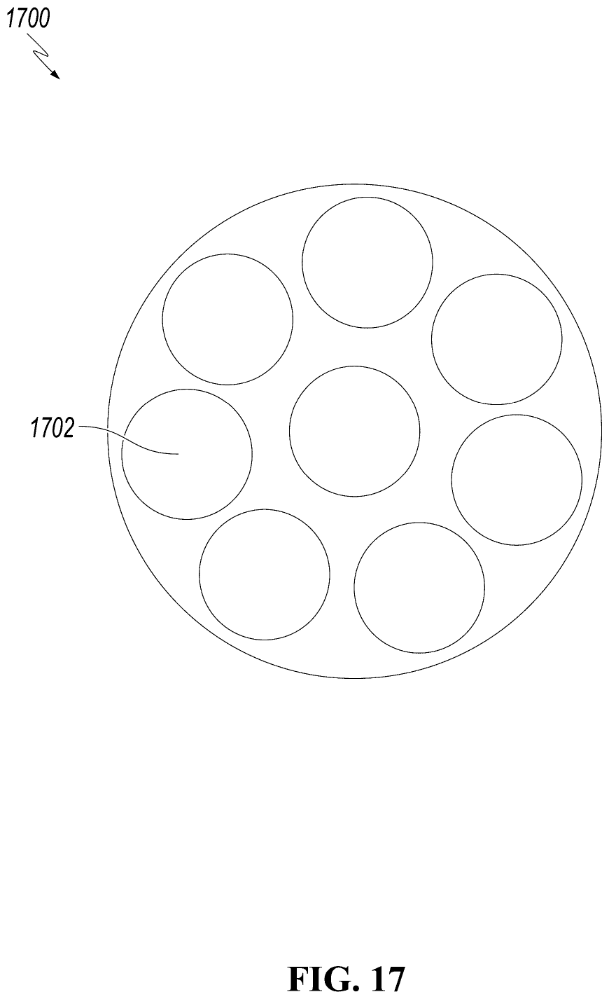

In some implementations, a multiport waveguide 1700 can be included in any of the arrangements described herein. FIG. 17 illustrates an example of such a multi-port waveguide in a variety of positions. The multi-port waveguide 1700 defines radially-positioned ports 1702 arranged to selectively provide the electromagnetic wave in one or more modes to the set of waveguides (302, 1102, 1504). In some implementations, at least one of the radially-positioned ports 1702 can be configured to convey a data signal means, liquids, and/or additives into the borehole 148. In implementations where a data signal means is used, such a means can include a fiber optic cable configured to convey at least one of acoustic data, temperature data, or pressure data from the borehole 148. Other data transmission means, such as conductive cables, EM transceivers, or mud-pulse components can be used without departing from this disclosure. In implementations where one of the ports 1702 can be used to convey liquids or additives down the wellbore, such a system can allow for treatment or control of the well without risking exposure of the electromagnetic system to contaminants.

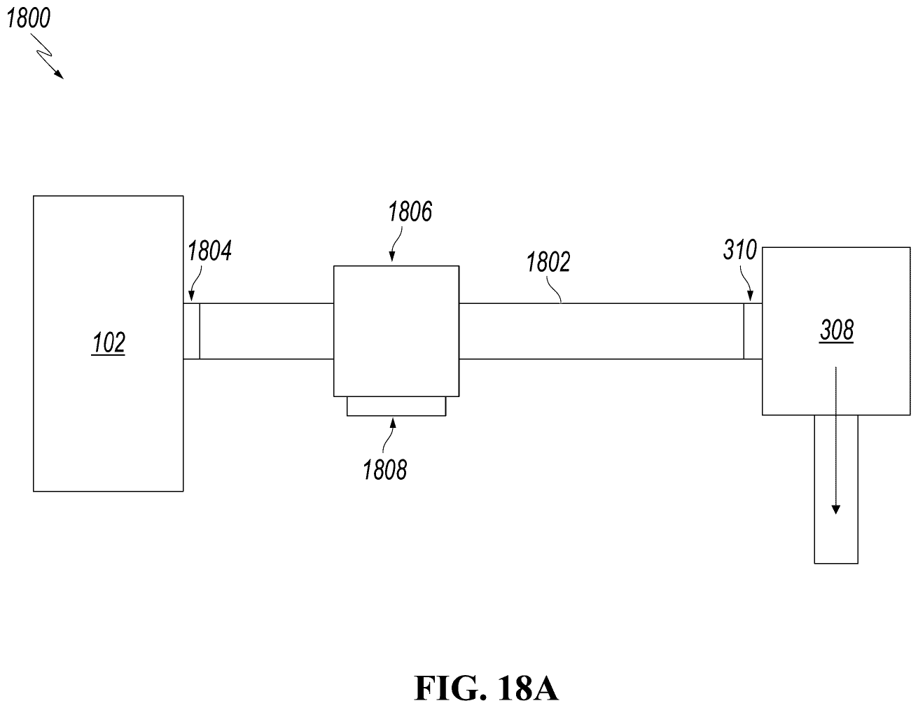

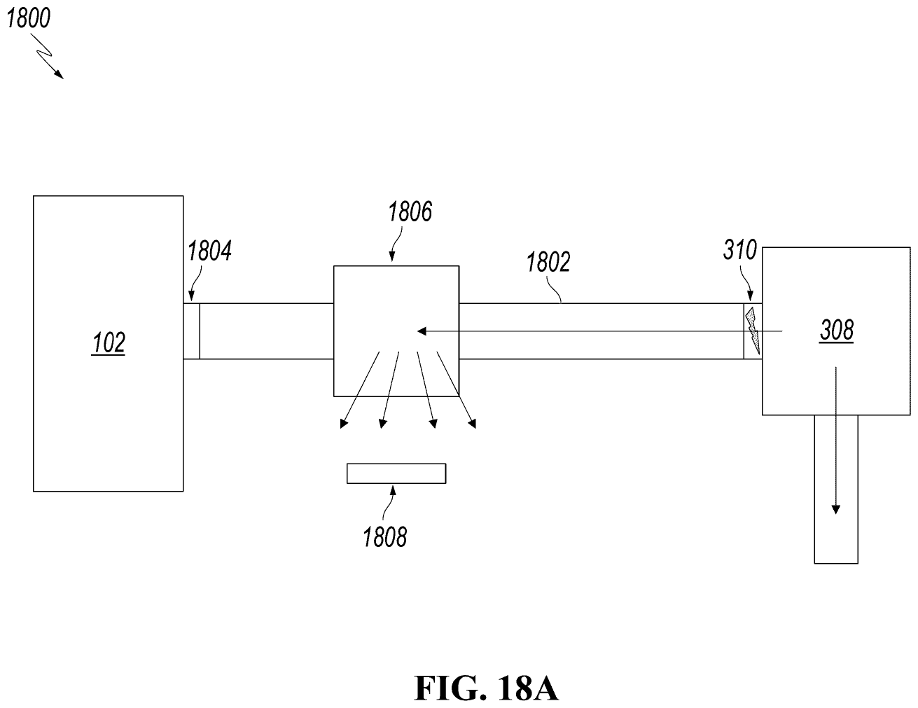

In instances where the barrier window 310 ruptures, high pressure gasses can rush from the transmission head 308 into the first plurality of waveguides 1802 towards the gyrotron 102, and potentially damage the gyrotron 102. To mitigate this, in some implementations, as shown in FIGS. 18A-18B, a pressure relief system 1800 is included. Is the system 1800, a pressure relief device 1806 is configured to relieve pressure within the first plurality of waveguides 1802 and direct the pressure away from a window 1804 of the gyrotron 102. In some implementations, the MOU 1106 previously describe is integrated with the pressure relief device 1806 as a single unit, though such components can be separate and distinct without departing from this disclosure. In operation, when the barrier window 310 is broken, cracked, or otherwise compromised (as shown in FIG. 18B), pressure entering the first plurality of waveguides 1802 triggers the pressure relief device 1806 to direct the pressure away from the gyrotron 102. In the illustrated implementation, a cap 1808 is ejected from the pressure relief device 1806 upon receipt of the pressure. The cap 1808 can be held in place by magnets, springs, shear fasteners, a vacuum within the first plurality of waveguides 1802, or with any other securing techniques that can be calibrated for a desired rupture pressure. Other pressure relief devices can be used without departing from this disclosure, for example, a poppet pressure safety valve, a pilot style pressure safety valve, or a rupture disc can be used.

Some implementations of the current subject matter can provide a multi-piece corrugated waveguide suitable for use with electromagnetic wave transmission. For example, some implementations of the current subject matter can enable formation and use of a corrugated waveguide suitable for drilling a borehole of a well using millimeter electromagnetic waves in a variety of transmission modes, such as HE₁₁ mode. Some implementations of the multi-piece configuration of the corrugated waveguide described herein can reduce the complexity of manufacturing such apparatuses by providing corrugated waveguide features via a coil spring that can be inserted into a tube, instead of machining the corrugation features within long lengths of tube. As a result, some implementations of the MCG described herein can be manufactured at higher precision tolerances than forming the corrugated features via machining, tapping, or boring, which can leave machined material inside the waveguide and reduce electromagnetic transmissivity. Additionally, coating or plating components of the MCG can be more readily preformed because insulative, dielectric, or conductive materials can be applied to individual components during manufacturing instead of coating or plating long lengths of tube with insulative, dielectric or conductive materials after corrugation features have been machined into the long tube lengths.

Certain exemplary embodiments have been described to provide an overall understanding of the principles of the structure, function, manufacture, and use of the systems, devices, and methods disclosed herein. One or more examples of these embodiments have been illustrated in the accompanying drawings. Those skilled in the art will understand that the systems, devices, and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention. Further, in the present disclosure, like-named components of the embodiments generally have similar features, and thus within a particular embodiment each feature of each like-named component is not necessarily fully elaborated upon.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

One skilled in the art will appreciate further features and advantages of the invention based on the above-described embodiments. Accordingly, the present application is not to be limited by what has been particularly shown and described, except as indicated by the appended claims. All publications and references cited herein are expressly incorporated by reference in their entirety.

What is claimed is:

1. A system comprising:
a millimeter (mm) wave emitter configured to emit an electromagnetic wave in a first mode; and
an enclosure configured to receive the electromagnetic wave from the mm wave emitters via a first plurality of waveguides positioned between the mm wave emitter and the enclosure, the enclosure comprising a plurality of components configured to manage transmission of the electromagnetic wave in the first mode to a second waveguide positioned relative to a borehole of a well to be formed via the electromagnetic wave transmitted through the second waveguide, the plurality of components comprising at least one of:
a first port at which a gas is received;
at least one mirror configured to adjust a direction or a diameter of the electromagnetic wave provided to the second waveguide;
a frequency sensor configured to sample the electromagnetic wave;
at least one power measurement sensor configured to measure a power of the electromagnetic wave;
at least one arc detector configured to detect an arc event responsive to transmitting the electromagnetic wave to the second waveguide;
a cooled wire grid configured to direct electromagnetic radiation in the first mode reflected from the borehole away from the mm wave emitter; or
a load cell provided on an exterior surface of the enclosure.

2. The system of claim 1, wherein the first plurality of waveguides is coupled via one or more miter bends.

3. The system of claim 2, wherein the first plurality of waveguides and/or the one or more miter bends include a plurality of corrugation features on an inner surface on each waveguide of the first plurality of waveguides and an inner surface of the one or more miter bends, the plurality of corrugation features configured to control a mode and a polarization of the electromagnetic wave as the electromagnetic wave propagates through the first plurality of waveguides and/or the one or more miter bends.

4. The system of claim 3, alternatively comprising one or more bends in place of the one or more miter bends.

5. The system of claim 3, further comprising a barrier window positioned between the mm wave emitter and the borehole, the barrier window configured to protect the mm wave emitter from a vacuum force or a pressure force.

6. The system of claim 3, wherein the first plurality of waveguides and/or the second waveguide include one or more tapered portions, wherein a first end of a tapered portion is adjacent to at least one miter bend and a second end of the tapered portion is opposite the first end, the first end having a larger diameter than the second end.

7. The system of claim 1, wherein the mm wave emitter is positioned on a surface of earth through which the borehole of the well is formed, the enclosure is positioned above the borehole of the well, and the electromagnetic wave is a millimeter electromagnetic wave.

8. The system of claim 1, wherein the direction of the electromagnetic wave provided to the second waveguide is adjusted via a mirror and the diameter of the electromagnetic wave is provided to the second waveguide is adjusted via a focusing mirror.

9. The system of claim 1, further comprising one or more fluid conduits arranged adjacent to the exterior surface of the first plurality of waveguides to cool the first plurality of waveguides.

10. The system of claim 1, wherein the second waveguide is configured to translate into or out of the borehole along a stroke length.

11. The system of claim 1, further comprising an electrical breaker positioned between the mm wave emitter and the first plurality of waveguides, the electrical breaker configured to electrically isolate the mm wave emitter from the first plurality of waveguides.

12. The system of claim 1, further comprising a matching optics unit (MOU) positioned between the mm wave emitter and a first waveguide of the first plurality of waveguides, the MOU configured to align the electromagnetic wave emitted from the mm wave emitter with an axis extending through the first waveguide of the first plurality of waveguides.

13. The system of claim 12, wherein the MOU is coupled to an outlet of the mm wave emitter by a vacuum within the first plurality of waveguides, the vacuum retaining the MOU to an output of the mm wave emitter, the coupling configured to be broken when the first waveguide experiences a sufficiently large mechanical load to separate the MOU from the outlet of the mm wave emitter.

14. The system of claim 1, wherein at least one waveguide of the first plurality of waveguides includes an expansion joint configured to expand or contract responsive to thermal expansion or contraction of the at least one waveguide.

15. The system of claim 1, further comprising a combiner unit configured to couple a second mm wave emitter emitting a second electromagnetic wave in the first mode.

16. The system of claim 15, wherein the second mm wave emitter is configured to emit the second electromagnetic wave with a frequency different from the first electromagnetic wave.

17. The system of claim 15, wherein the second mm wave emitter is configured to emit the second electromagnetic wave with a polarization different from the first electromagnetic wave.

18. The system of claim 1, further comprising:
a pressure relief device within the first plurality of waveguides, the pressure relief device arranged and configured to direct pressure away from the mm wave emitter.

19. An apparatus comprising:
an enclosure configured to receive an electromagnetic wave from a mm wave emitter via a first waveguide positioned between the mm wave emitter and the enclosure, the enclosure comprising a plurality of components configured to manage transmission of the electromagnetic wave to a second waveguide positioned relative to a borehole of a well to be formed via the electromagnetic wave transmitted through the second waveguide, the plurality of components comprising at least one of:
a first port at which a gas is received;
at least one mirror configured to adjust a direction or a diameter of the electromagnetic wave provided to the second waveguide;
a frequency sensor configured to sample the electromagnetic wave,
at least one power measurement sensor configured to measure a power of the electromagnetic wave;
at least one arc detector configured to detect an arc event responsive to transmitting the electromagnetic wave to the second waveguide;
a cooled wire grid configured to direct electromagnetic radiation reflected from the borehole away from the mm wave emitter;
a load cell provided on an exterior surface of the enclosure; or
a barrier window.

20. The apparatus of claim 19, further comprising a diagnostic sampling device coupled to the enclosure, the diagnostic sampling device configured to measure at least one of a temperature, a standoff, mode purity, plasma formation, and a geometry of the borehole.

21. The apparatus of claim 19, wherein the at least one power measurement sensor comprises a first sensor configured to measure an amount of forward power of the electromagnetic wave passing through the enclosure toward the second waveguide and a second sensor configured to measure an amount of reverse power passing through the enclosure toward the mm wave emitter.

22. The apparatus of claim 19, further comprising a plasma trap configured to direct plasma away from the mm wave emitter, the plasma trap comprising
an electromagnet;
a permanent magnet;
a cavity of sufficient size to allow the electromagnetic wave to diverge; or
a gas flow port arranged to direct plasma away from the mm wave emitter when gas is flowing through the gas flow port.

23. The apparatus of claim 19, wherein the first port is configured to receive the gas from a gas source and to direct the gas into the borehole as a purge gas, wherein the purge gas is configured follow a flow passage into the borehole, the purge gas configured to cool a downhole end of the flow passage, cool the downhole end of the flow passage, and carry cuttings up an annulus defined by the flow passage and the borehole.

24. The apparatus of claim 19, wherein the enclosure further comprises a second port coupled to a pressure relief valve.

25. A method comprising:
receiving an electromagnetic wave by an enclosure from a first waveguide, wherein the enclosure includes a coating on an inner surfaces thereof;
directing the electromagnetic wave, by the enclosure, into a second waveguide positioned relative to a borehole of a well to be formed via the electromagnetic wave transmitted through the second waveguide; and
absorbing scattered electromagnetic radiation reflected from the borehole.

26. The method of claim 25, wherein the enclosure includes a flow passage defined by a conduit of material transparent to the electromagnetic wave, the method further comprising:
directing fluid through the enclosure, by the flow passage; and
carrying excess power from the enclosure by the fluid.

27. The method of claim 25, wherein the first waveguide or the second waveguide include a cooling mechanism on an exterior surface thereof, the method further comprising:
removing heat generated by the electromagnetic wave.

28. The method of claim 25, wherein the enclosure comprises a frequency sensor, wherein the frequency sensor is coupled to a computing device, the method further comprising:
determining if a sampled frequency of the electromagnetic wave is within a predetermined range of values stored in a memory of the computing device.
